(19) United States
(12) Patent Application Publication
(10) Pub. No.: US 2020/0365769 A1
(43) Pub. Date: Nov. 19, 2020

(54) SEMICONDUCTOR DEVICE

(71) Applicant: EPISTAR CORPORATION, Hsinchu (TW)

(72) Inventors: Yao-Ru CHANG, Hsinchu (TW); Wen-Luh LIAO, Hsinchu (TW); Yung-Fu CHANG, Hsinchu (TW); Hsiang CHANG, Hsinchu (TW); Meng-Yang CHEN, Hsinchu (TW); Yun-Hsin PANG, Hsinchu (TW); Yi HSIAO, Hsinchu (TW)

(73) Assignee: EPISTAR CORPORATION

(21) Appl. No.: 16/874,925

(22) Filed: May 15, 2020

Related U.S. Application Data
(60) Provisional application No. 62/848,788, filed on May 16, 2019.

(30) Foreign Application Priority Data
Apr. 30, 2020 (TW) 109114475

(51) Int. Cl. H01L 33/40; H01L 33/62

(52) U.S. Cl. CPC H01L 33/405; H01L 33/62

(57) ABSTRACT

A semiconductor device is provided, which includes a base, a semiconductor structure and a conductive reflective structure. The base has a first surface and a second surface opposite to the first surface. The semiconductor structure is located on the first surface. The conductive reflective structure is located on the second surface and includes a metal oxide structure and a metal structure. The metal oxide structure is located between the metal structure and the base. The metal oxide structure physically contacts the second surface.

### CROSS REFERENCE TO RELATED APPLICATIONS

This application claims the right of priority based on U.S. provisional patent application Ser. No. 62/848,788, filed on May 16, 2019 and TW application Serial No. 109114475, filed on Apr. 30, 2020, which also claims the benefit of U.S. provisional patent application Ser. No. 62/848,788, and each of which is incorporated by reference herein in their entirety.

### FIELD OF DISCLOSURE

The present disclosure relates to a semiconductor device and in particular to a semiconductor light-emitting device such as a light-emitting diode.

### BACKGROUND OF THE DISCLOSURE

Semiconductor devices are widely used in many applications. Various researches and developments of related material used in the semiconductor devices have been conducted. For example, a III-V group semiconductor material containing a III-group element and a V-group element may be applied to various optoelectronic devices, such as light emitting diodes (LEDs), laser diodes (LDs), photoelectric detectors, solar cells, or power devices, such as switches or rectifiers. In recent years, the optoelectronic devices have been widely applied in fields including lighting, medical, display, communication, and sensing systems. The light-emitting diode, which is one of the semiconductor light-emitting devices, has the advantages of low energy consumption and long operating lifetime, and is therefore widely used in various fields. With the development of technology, there are still needs for the research and development of semiconductor devices.

### SUMMARY OF THE DISCLOSURE

The present disclosure provides a semiconductor device. The semiconductor device includes a base, a semiconductor structure and a conductive reflective structure. The base has a first surface and a second surface opposite to the first surface. The semiconductor structure is located on the first surface. The conductive reflective structure is located on the second surface and includes a metal oxide structure and a metal structure. The metal oxide structure is located between the metal structure and the base. The metal oxide structure physically contacts the second surface.

### BRIEF DESCRIPTION OF THE DRAWINGS

FIG. 1A shows a schematic top view of a semiconductor device in accordance with an embodiment of the present disclosure.

FIG. 1B shows a schematic sectional view of the semiconductor device along A-A′ line in FIG. 1A.

FIG. 1C shows a schematic sectional view of the semiconductor device in accordance with an embodiment of the present disclosure.

FIG. 1D shows a schematic sectional view of the semiconductor device in accordance with an embodiment of the present disclosure.

FIG. 1E shows a schematic sectional view of the semiconductor device in accordance with an embodiment of the present disclosure.

FIG. 1F shows a schematic sectional view of the semiconductor device in accordance with an embodiment of the present disclosure.

FIG. 1G shows a schematic sectional view of the semiconductor device in accordance with an embodiment of the present disclosure.

FIG. 1H shows a schematic sectional view of the semiconductor device in accordance with an embodiment of the present disclosure.

FIG. 1I shows a schematic sectional view of the semiconductor device in accordance with an embodiment of the present disclosure.

FIG. 1J shows a schematic sectional view of the semiconductor device in accordance with an embodiment of the present disclosure.

FIG. 2A shows a schematic top view of a semiconductor device in accordance with an embodiment of the present disclosure.

FIG. 2B shows a schematic sectional view of the semiconductor device in FIG. 2A along B-B′ line.

FIG. 3 shows a schematic sectional view of the semiconductor device in accordance with an embodiment of the present disclosure.

FIG. 4A shows a schematic sectional view of the semiconductor device in accordance with an embodiment of the present disclosure.

FIG. 4B shows a schematic view of a patterned metal structure in accordance with an embodiment of the present disclosure.

FIG. 4C shows an enlarged view of a unit pattern in FIG. 4B.

FIG. 4D shows a schematic view of a patterned metal structure in accordance with an embodiment of the present disclosure.

FIG. 5 shows a schematic sectional view of the semiconductor device in accordance with an embodiment of the present disclosure.

FIG. 6 shows a schematic sectional view of the semiconductor device in accordance with an embodiment of the present disclosure.

FIG. 7 shows a schematic sectional view of a semiconductor package structure in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same numerals. Furthermore, a shape or a thickness of a component in the drawings may be enlarged or reduced. Particularly, it should be noted that a component which is not illustrated or described in drawings or description may be in a form that is known by a person skilled in the art.

In the present disclosure, if not otherwise specified, the general formula InGaAs represents In_{z1}Ga_{1-z1}As, wherein 0<z1<1; the general formula InAlAs represents In_{z2}Al_{1-z2}As, wherein 0<z2<1; the general formula InGaAsP represents In_{z3}Ga_{1-z3}As_{z4}P_{1-z4}, wherein 0<z3<1 and 0<z4<1; the general formula AlGaInAs represents (Al_{z5}Ga_{(1-z5)})_{z6}In_{1-z6}As, wherein 0<z5<1 and 0<z6<1; the general formula AlGaInP represents (Al_{z7}Ga_{(1-z7)})_{z8}In_{1-z8}P, wherein 0<z7<1 and 0<z8<1. The content of each element may be adjusted for different purposes, for example, for adjusting the energy gap or the peak wavelength or dominant wavelength when the semiconductor device is a light-emitting device. However, the present disclosure is not limited thereto. Qualitative or quantitative analysis of the composition and/or dopant contained in each layer of the semiconductor device of the present disclosure may be conducted by any suitable method, for example, a secondary ion mass spectrometer (SIMS). A thickness of each layer may be obtained by any suitable method, such as a transmission electron microscopy (TEM) or a scanning electron microscope (SEM). In addition, the dopant mentioned in this disclosure may be added intentionally or unintentionally. In an intentional addition, for example, the dopant may be added by in-situ doping during epitaxial growth and/or by implantation using a p-type or n-type dopant after epitaxial growth. In an unintentional addition, the presence of the dopant may be diffused by the subsequent manufacturing process.

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

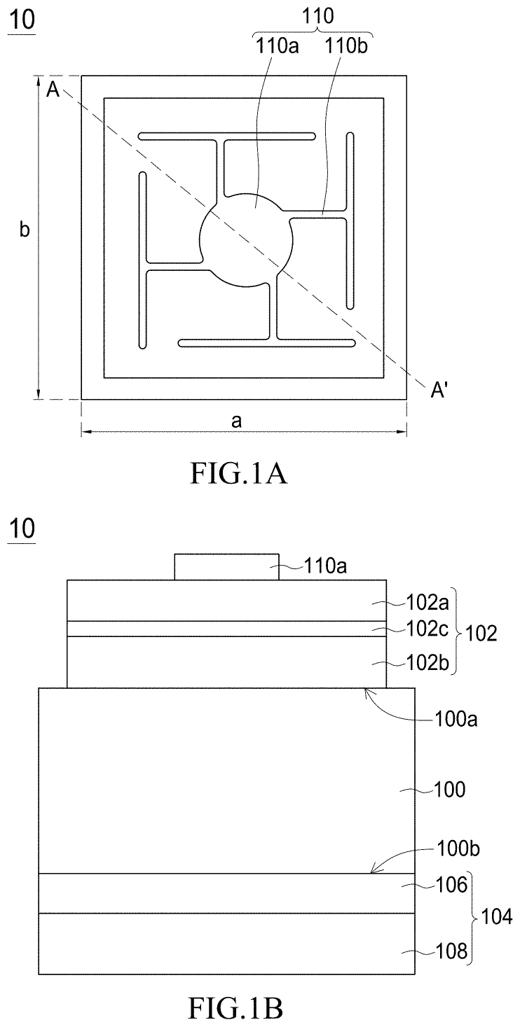

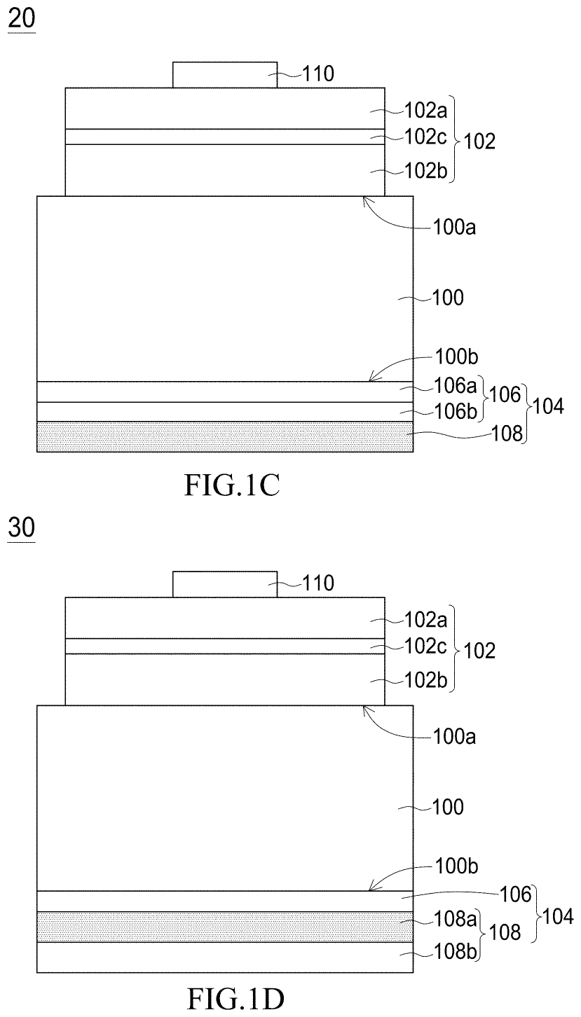

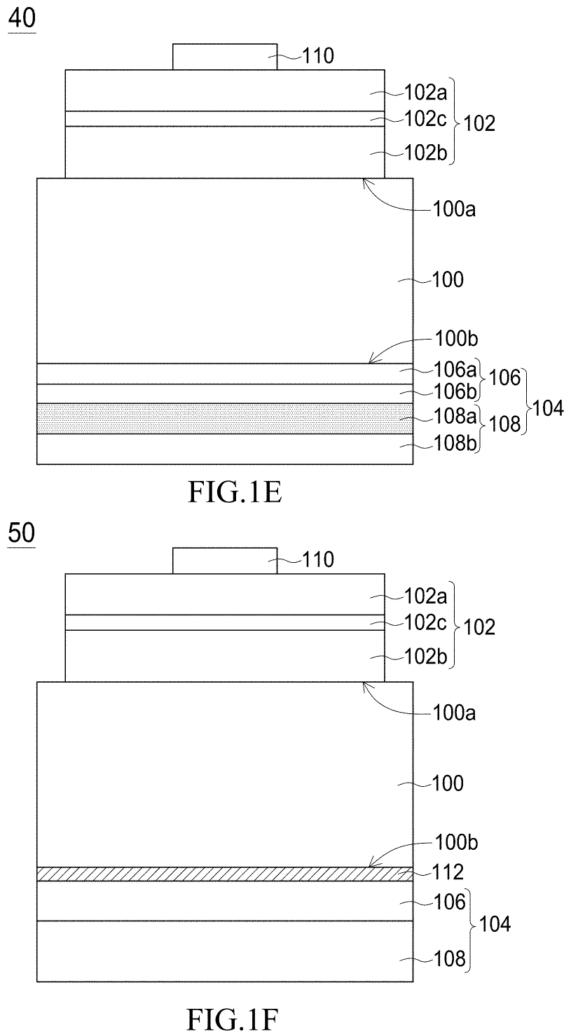

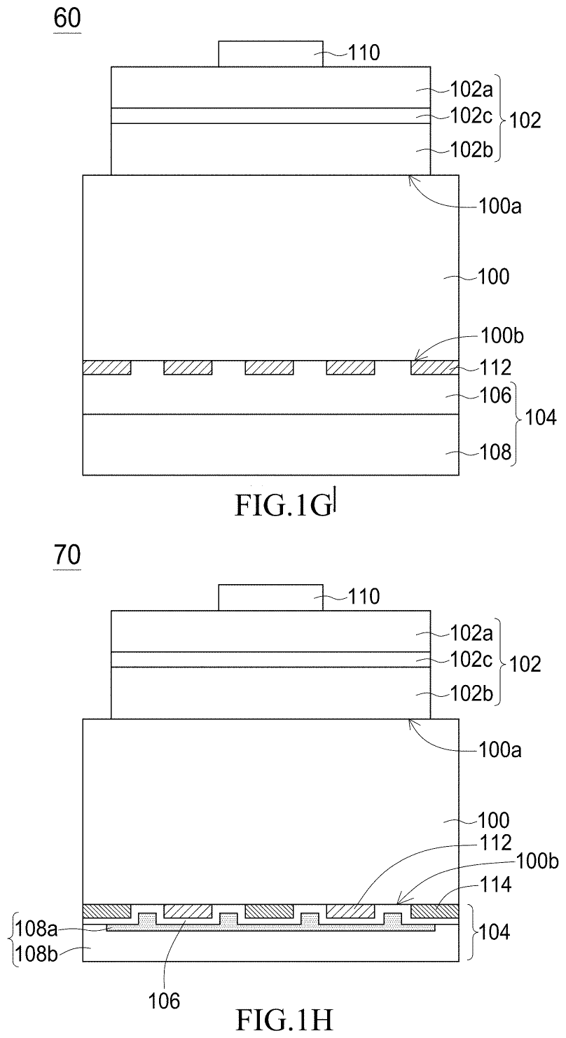

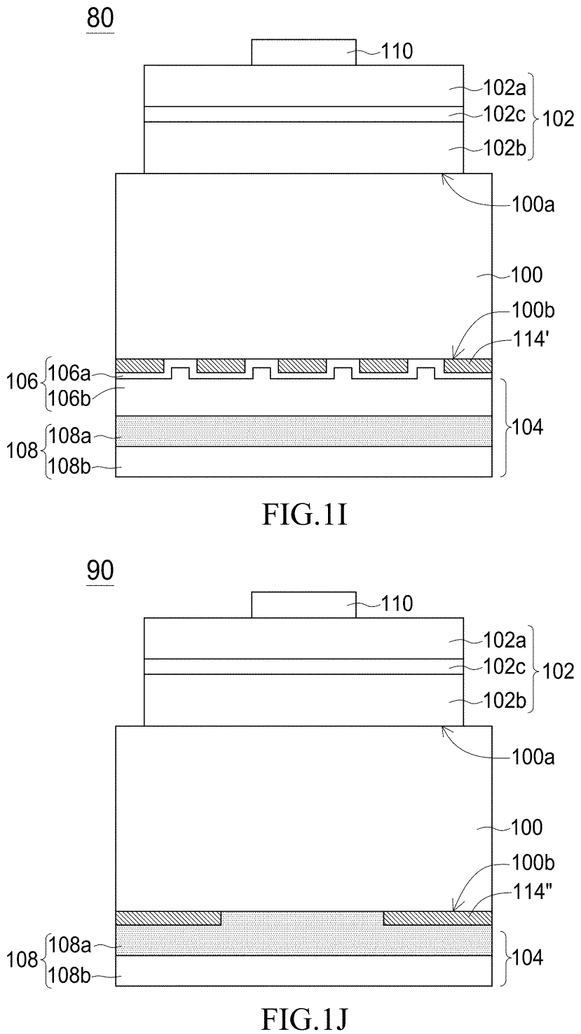

FIG. 1A shows a schematic top view of a semiconductor device 10 in accordance with an embodiment of the present disclosure. FIG. 1B shows a schematic sectional view of the semiconductor device 10 along A-A′ line in FIG. 1A.

The semiconductor device 10 of the present disclosure may be a semiconductor light-emitting device, such as a light emitting diode (LED) or a laser diode (LD), or a detection device such as a photodiode (PD). The semiconductor device 10 may include a single heterostructure (SH), a double heterostructure (DH), a double-side double heterostructure (DDH), or multiple quantum wells (MQW) structure. In the embodiment, the semiconductor device 10 includes a base 100, a semiconductor structure 102, a conductive reflective structure 104, and a first electrode 110. The base 100 has a first surface 100a and a second surface 100b opposite to the first surface 100a. The semiconductor structure 102 is located on the first surface 100a of the base 100, and the conductive reflective structure 104 is located on the second surface 100b of the base 100. In this embodiment, the semiconductor device 10 has a rectangular shape and has a length a and a width b in a top view. In an embodiment, the length a and the width b of the semiconductor device 10 may be approximately equal. In some embodiments, the length a and the width b may be respectively greater than or equal to 100 μm and less than or equal to 500 μm, such as 200 μm, 250 μm, 300 μm, 350 μm, 400 μm, or 450 μm.

The base 100 may be a conductive substrate including gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si). The base 100 may include a dopant and may have a doping concentration. The dopant may be a non-metallic element (such as carbon (C), sulfur (S), or silicon (Si)) or a metal element (such as iron (Fe) or zinc (Zn)). The doping concentration in the base 100 may fall within a range of 5×10¹⁷ cm⁻³ to 5×10¹⁸ cm⁻³, 3×10¹⁸ cm⁻³ or less, or even 2.5×10¹⁸ cm⁻³ or less, or 2×10¹⁸ cm⁻³ or less. In some embodiments, when the doping concentration of the base 100 is 1×10¹⁸ cm⁻³ or more, it can ensure that the base has a good conductivity. In some embodiments, when the doping concentration of the base 100 falls within a range of 3×10¹⁸ cm⁻³ or less, the semiconductor device may have a better luminous efficiency. The base 100 may be a growth substrate or a support substrate. Specifically, the semiconductor structure 102 may be obtained by epitaxial growth, and the base 100 may be the growth substrate for growing the semiconductor structure 102, or the base 100 may be the support substrate to which the semiconductor structure 102 is bonded by a bonding layer after the growth substrate is removed.

When the semiconductor device 10 is a light-emitting device, the semiconductor structure 102 may emit a radiation. The radiation may be non-coherent or coherent light. The radiation can be red light or infrared light such as near-infrared light. When the radiation is near-infrared light, it may have a peak wavelength between 800 nm and 2000 nm (both included), such as 810 nm, 850 nm, 910 nm, 940 nm, 1050 nm, 1070 nm, 1100 nm, 1200 nm, 1300 nm, 1400 nm, 1450 nm, 1550 nm, 1600 nm, 1650 nm, or 1700 nm. The substrate 10 may be transparent, translucent (semi-transparent), or opaque to the radiation. When the semiconductor device 10 emits near-infrared light having a peak wavelength greater than 1000 nm, the substrate 10 can have a transmittance greater than 30% or an absorption rate of 30% or less to the near-infrared light. In some embodiments, the base 100 may have a thickness greater than or equal to 60 μm and less than or equal to 250 μm, such as 100 μm, 130 μm, 140 μm, 150 μm, 160 μm, 170 μm, 180 μm, 200 μm, or 230 μm.

The semiconductor structure 102 may include a first semiconductor layer 102a, a second semiconductor layer 102b, and an active region 102c between the first semiconductor layer 102a and the second semiconductor layer 102b. The semiconductor structure 102 may have a first width, and the base 100 may have a second width greater than the first width. The first semiconductor layer 102a and the second semiconductor layer 102b are respectively located on two sides of the active region 102c and physically contact the active region 102c. The first semiconductor layer 102a and the second semiconductor layer 102b have opposite conductivity types to provide electrons and holes or holes and electrons. For example, the conductivity type of the first semiconductor layer 102a is n-type and the conductivity type of the second semiconductor layer 102b is p-type, or the conductivity type of the first semiconductor layer 102a is p-type and the conductivity type of the second semiconductor layer 102b is n-type.

The first semiconductor layer 102a and the second semiconductor layer 102b may include aluminum (Al), gallium (Ga), arsenic (As), phosphorus (P), or indium (In), and may not include nitrogen (N). In an embodiment, the first semiconductor layer 102a and the second semiconductor layer 102b respectively include at least two elements selected from aluminum (Al), gallium (Ga), arsenic (As), phosphorus (P), and indium (In). Specifically, the first semiconductor layer 102a and the second semiconductor layer 102b may respectively include a binary, ternary, or quaternary III-V semiconductor material, such as InP, GaAs, InGaAs, or InAlAs. In an embodiment, the first semiconductor layer 102a and the second semiconductor layer 102b have the same material. For example, both the first semiconductor layer 102a and the second semiconductor layer 102b include InP, GaAs, InGaAs, or InAlAs. In addition, the conductivity types of the first semiconductor layer 102a and the second semiconductor layer 102b can be adjusted by adding different dopants, such as magnesium (Mg), zinc (Zn), carbon (C), silicon (Si), or tellurium (Te). In an embodiment, the dopant in the first semiconductor layer 102a includes silicon (Si) and the dopant in the second semiconductor layer 102b includes zinc (Zn). The active region 102c may include a group III-V semiconductor material. The group III-V semiconductor material may include aluminum (Al), gallium (Ga), arsenic (As), phosphorus (P), or indium (In), and not include nitrogen (N). For example, the active region 102c may include a quaternary III-V semiconductor material, such as InGaAsP or AlGaInAs.

The conductive reflective structure 104 may include a metal oxide structure 106 and a metal structure 108. The conductive reflective structure 104 can reflect the radiation emitted by the active region 102c towards the first semiconductor layer 102a and out of the semiconductor device 10. In this embodiment, the metal oxide structure 106 physically contacts the second surface 100b of the base 100. As shown in FIG. 1B, the metal oxide structure 106 can completely cover the second surface 100b of the base 100. The metal oxide structure 106 may be composed of a single layer or multiple layers. In an embodiment, the metal oxide structure 106 has a transmittance of more than 80% or even a transmittance of more than 90% to the light emitted by the active region 102c. The metal oxide structure 106 may be composed of a single layer or multiple layers, for example, composed of two or three layers. In addition, the metal oxide structure 106 is conductive and can be electrically connected to the metal structure 108 and the base 100. The metal oxide structure 106 may include a metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), or indium zinc oxide (IZO). In some embodiments, the metal oxide structure 106 benefits the current distribution in the semiconductor device.

The metal structure 108 may be composed of a single layer or multiple layers, and the metal structure 108 may be electrically connected to an external power source. The material of the metal structure 108 may include metal or alloy. When the metal structure 108 is composed of multiple layers, the multiple layers may include different metals or alloys. In an embodiment, each of the multiple layers may include metal or alloy different from others. In some embodiments, the metal structure 108 is composed of three or more layers of metal or alloy. The metal or alloy can be selected from In, Sn, Al, Au, Pt, Zn, Ag, Ti, Pb, Ge, Cu, Ni, W, Pt, AuBe, AuGe, AuZn, PbSn, and GeAuNi. In an embodiment, the metal structure 108 includes at least one of Ag, Ti, Pt, and Au. In an embodiment, the metal structure 108 includes a reflective layer (such as an Ag or Au layer) adjacent to the metal oxide structure 106. The reflective layer can reflect the radiation emitted by the active region 102c. In an embodiment, the metal structure 108 includes at least two layers of metal selected from Ag, Ti, Pt, and Au. For example, the metal structure 108 may include Ag/Ti, Ti/Pt/Au, Ag/Ti/Pt/Au, Ag/Ti/Pt/Ti/Pt/Au, Au/Ti/Pt/Au or Au/Ti/Pt/Ti/Pt/Au.

In some embodiments, the conductive reflective structure 104 can serve as an electrode and can be electrically connected to an external power source. That is, the conductive reflective structure 104 has functions of reflecting the radiation emitted by the active region 102c and conducting current at the same time. In addition, the metal structure 108 may completely or partially cover a lower surface of the base 100 (e.g. the second surface 100b) or a lower surface of the metal oxide structure 106 in the semiconductor device 10. In some embodiments, the conductive reflective structure 104 may only include the metal structure 108 and not include the metal oxide structure 106. The metal structure 108 may physically contact the second surface 100b of the base 100.

The first electrode 110 is located on the semiconductor structure 102 for electrically connecting with an external power source and the active region 102c. The first electrode 110 includes a main electrode 110a and an extension electrode 110b. As shown in FIG. 1A, the first electrode 110 of the semiconductor device may include one main electrode 110a and a plurality of extension electrodes 110b. For example, the number of the extension electrodes 110b can be four or more. In this embodiment, the main electrode 110a has a circular shape, and each extension electrode 110b is T-shaped. As shown in FIG. 1A, the main electrode 110a is located at the center of an upper surface of the semiconductor device 10, and the plurality of extension electrodes 110b surround the main electrode 110a and are connected to the main electrode 110a. The main electrode 110a may have a width (such as the diameter of the main electrode 110a when being circular) falling within a range of 50 μm to 150 μm. The extension electrode 110b may have a width falling within a range of 1 μm to 10 μm. Each extension electrode 110b has a width which can be 1/10 or less of the width of the main electrode 110a. The material of the first electrode 110 may include metal oxide, metal, or alloy. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include germanium (Ge), beryllium (Be), zinc (Zn), gold (Au), platinum (Pt), titanium (Ti), aluminum (Al), nickel (Ni), or copper (Cu). The alloy may include at least two selected from the above-mentioned metals, such as germanium gold nickel (GeAuNi), beryllium gold (BeAu), germanium gold (GeAu) or zinc gold (ZnAu). In this embodiment, the semiconductor device 10 is a vertical type semiconductor light-emitting device, that is, two electrodes (the first electrode 110 and the conductive reflective structure 104 which serve as another electrode) are respectively located on two opposite sides of the base 100.

FIG. 1C shows a schematic sectional view of the semiconductor device 20 in accordance with an embodiment of the present disclosure.

In this embodiment, the metal oxide structure 106 includes a first metal oxide layer 106a and a second metal oxide layer 106b, and the metal structure 108 is a single layer. The first metal oxide layer 106a can be adjacent to the base 100 and physically contact the second surface 100b of the base 100. The second metal oxide layer 106b can be adjacent to the first metal oxide layer 106a and physically contact the metal structure 108. The thickness of the second metal oxide layer 106b may be larger or smaller than that of the first metal oxide layer 106a. The materials of the first metal oxide layer 106a and the second metal oxide layer 106b may be the same or different. The first metal oxide layer 106a may include a first conductive material and the second metal oxide layer 106b may include a second conductive material. In an embodiment, the electrical resistivity of the first metal oxide layer 106a is smaller than that of the second metal oxide layer 106b. The first metal oxide layer 106a and the second metal oxide layer 106b may respectively include a metal oxide. The metal oxide can be selected from indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) and indium zinc oxide (IZO). In an embodiment, the first metal oxide layer 106a and the second metal oxide layer 106b have one same metal element such as indium (In). In an embodiment, the first metal oxide layer 106a includes indium tin oxide (ITO) and the second metal oxide layer 106b includes indium zinc oxide (IZO).

For the positions, materials, and related descriptions of other layers or structures, the foregoing embodiments can be referred to, and are not repeatedly described herein.

FIG. 1D shows a schematic sectional view of the semiconductor device 30 in accordance with an embodiment of the present disclosure.

In this embodiment, the metal oxide structure 106 has a single layer, and the metal structure 108 has multiple layers, including a first metal layer 108a and a second metal layer 108b. The materials of the first metal layer 108a and the second metal layer 108b may be the same or different. In an embodiment, the first metal layer 108a and/or the second metal layer 108b can be made of metal or alloy. The metal or alloy can be selected from In, Sn, Al, Au, Pt, Zn, Ag, Ti, Pb, Ge, Cu, Ni, W, Pt, AuBe, AuGe, AuZn, PbSn, and GeAuNi. In an embodiment, one of the first metal layer 108a and the second metal layer 108b may be patterned. For example, the patterned first metal layer 108a may be located at the center of a bottom surface of the base 100 and partially cover the metal oxide structure 106. The second metal layer 108b may cover the first metal layer 108a and physically contact the metal oxide structure 106. In other words, the first metal layer 108a may have a width smaller than that of the second metal layer 108b and/or the metal oxide structure 106. In this way, a damage (such as oxidation) to the first metal layer 108a, which is caused by the first metal layer 108a directly contacting the external environment (such as air), can be avoided. Thereby, reduction in reflection which may result from the damage can also be avoided.

For the positions, materials, and related descriptions of other layers or structures, the foregoing embodiments can be referred to, and are not repeatedly described herein.

FIG. 1E shows a schematic sectional view of the semiconductor device 40 in accordance with an embodiment of the present disclosure.

In this embodiment, the metal oxide structure 106 and the metal structure 108 respectively include multiple layers. As shown in FIG. 1E, the metal oxide structure 106 includes a first metal oxide layer 106a and a second metal oxide layer 106b, and the metal structure 108 includes a first metal layer 108a and a second metal layer 108b. For the materials and structural variations of the first metal oxide layer 106a, the second metal oxide layer 106b, the first metal layer 108a, and the second metal layer 108b, the foregoing embodiments can be referred to.

FIG. 1F, FIG. 1G, and FIG. 1H respectively show schematic sectional views of the semiconductor device 50, the semiconductor device 60 and the semiconductor device 70 in accordance with embodiments of the present disclosure.

In FIG. 1F, a contact layer 112 is further included between the conductive reflective structure 104 and the base 100. In some embodiments, the contact layer 112 can further improve the electrical connection characteristics between the metal oxide structure 106 and the base 100, for example, lowering the electrical resistivity. Regarding the materials and structural variations of the conductive reflective structure 104, the foregoing embodiments can be referred to. The material of the contact layer 112 may include a semiconductor material, metal, or alloy. The semiconductor material may be a compound semiconductor such as a binary III-V group semiconductor material (e.g. GaAs or GaP), or an element semiconductor such as silicon (Si). The metal or alloy may be selected from In, Sn, Al, Au, Pt, Zn, Ag, Ti, Pb, Ge, Cu, Ni, W, Pt, AuBe, AuGe, AuZn, PbSn, and GeAuNi. In some embodiments, when the conductive reflective structure 104 includes a metal oxide containing indium, such as indium tin oxide (ITO), the contact layer 112 may include a conductive semiconductor material such as silicon (Si).

In an embodiment, the contact layer 112 may completely cover the second surface 100b of the base 100, as shown in FIG. 1F. In an embodiment, the contact layer 112 may be patterned and cover a portion of the second surface 100b of the base 100, as shown in FIG. 1G. According to an embodiment, the contact layer 112 may have a two-dimensional dot pattern in a top view.

In an embodiment, in addition to the contact layer 112, a dielectric material layer 114 can be further included between the metal oxide structure 106 and the base 100. As shown in FIG. 1H, both the contact layer 112 and the dielectric material layer 114 are patterned and physically contact the base 100. In this embodiment, on the second surface 100b of the base 100, the contact layer 112 and the dielectric material layer 114 are separated by a distance. The metal oxide structure 106 in the conductive reflective structure 104 may conformally cover the contact layer 112 and the dielectric material layer 114. The material of the dielectric material layer 114 may be SiO₂, MgF₂, SiNₓ, Al₂O₃, or a combination thereof. The first metal layer 108a may be a patterned metal layer located at the center of a bottom surface of the conductive reflective structure 104 and may partially cover the metal oxide structure 106. The second metal layer 108b may cover the first metal layer 108a and physically contact the metal oxide structure 106.

For the positions, materials, and related descriptions of other layers or structures, the foregoing embodiments can be referred to, and are not repeatedly described herein.

FIG. 1I shows a schematic sectional view of the semiconductor device 80 in accordance with an embodiment of the present disclosure.

As shown in FIG. 1I, in this embodiment, there is no contact layer 112 located between the metal oxide structure 106 and the base 100. The dielectric material layer 114 ‘may partially cover the second surface 100b of the base 100. In this embodiment, the dielectric material layer 114’ is a patterned layer. The material of the dielectric material layer 114′ may be SiO₂, MgF₂, SiNₓ, Al₂O₃, or a combination thereof. As shown in FIG. 1I, the patterned dielectric material layer 114′ may physically contact the base 100. The first metal oxide layer 106a may conformally cover the dielectric material layer 114′ and the base 100. The second metal oxide layer 106b may cover the first metal oxide layer 106a. During operation of the semiconductor device 80, a portion where the first metal oxide layer 106a physically contacts the base 100 is a conductive region, so that a current path can be formed. In some embodiments, by having the patterned dielectric material layer 114′, the current spreading and uniformity of light emission of the semiconductor device 80 can be further improved.

For the positions, materials, and related descriptions of other layers or structures, the foregoing embodiments can be referred to, and are not repeatedly described herein.

FIG. 1J shows a schematic sectional view of the semiconductor device 90 in accordance with an embodiment of the present disclosure.

In this embodiment, the semiconductor device 90 does not have a metal oxide structure 106 and includes a dielectric material layer 114″ located between the metal structure 108 and the base 100. The metal structure 108 may include a first metal layer 108a and a second metal layer 108b. As shown in FIG. 1J, the dielectric material layer 114″ partially covers the second surface 100b of the base 100. For example, the dielectric material layer 114″ may cover the surface of the base 100 near an edge of the semiconductor device 90. The first metal layer 108a may cover the dielectric material layer 114″ and physically contact the base 100. The material of the dielectric material layer 114″ may be SiO₂, MgF₂, SiNₓ, Al₂O₃, or a combination thereof. For the materials and structural variations of the first metal layer 108a and the second metal layer 108b, the foregoing embodiments can be referred to.

For the positions, materials, and related descriptions of other layers or structures, the foregoing embodiments can be referred to, and are not repeatedly described herein.

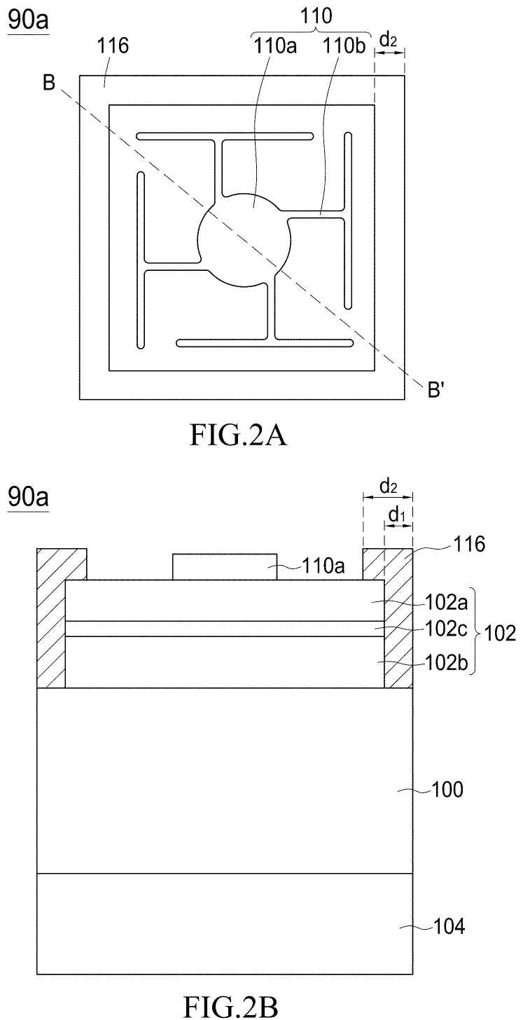

FIG. 2A shows a schematic top view of a semiconductor device 90a in accordance with an embodiment of the present disclosure. FIG. 2B shows a schematic sectional view of the semiconductor device 90a in FIG. 2A along B-B′ line.

The semiconductor device 90a of this embodiment further includes a protective layer 116 covering at least a sidewall of the semiconductor structure 102. As shown in FIG. 2B, the protective layer 116 covers a portion of an upper surface of the base 100, the sidewall of the semiconductor structure 102, and a portion of the upper surface of the semiconductor structure 102. The material of the protective layer 116 may include a silicon nitride or silicon oxide, such as SiO₂ or SiNₓ. The thickness of the protective layer 116 may be in a range of 1000 Å to 8000 Å (such as 1500 Å, 2000 Å, 3000 Å, 6000 Å, 6500 Å, 7000 Å, or 7500 Å) to obtain a better protection effect. In addition, as shown in the top view of FIG. 2A and the cross-sectional view of FIG. 2B, the portion where the protective layer 116 contacts the base 100 may have a width d1, and the protective layer 116 may have a width d2. In an embodiment, the width d1 and the width d2 satisfies 1<d2/d1≤3. For example, d2/d1 may be 1.2, 1.5, 1.8, 2, 2.5, or 2.8. In some embodiments, the protective layer 116 is provided to prevent the semiconductor structure 102 from being damaged, so that attenuation of brightness in the semiconductor device may be decreased, and the service life of the semiconductor device can be elongated. The conductive reflective structure 104 in this embodiment can be as described in any embodiment of the present disclosure. For the positions, materials, and related descriptions of other layers or structures, the foregoing embodiments can be referred to, and are not repeatedly described herein.

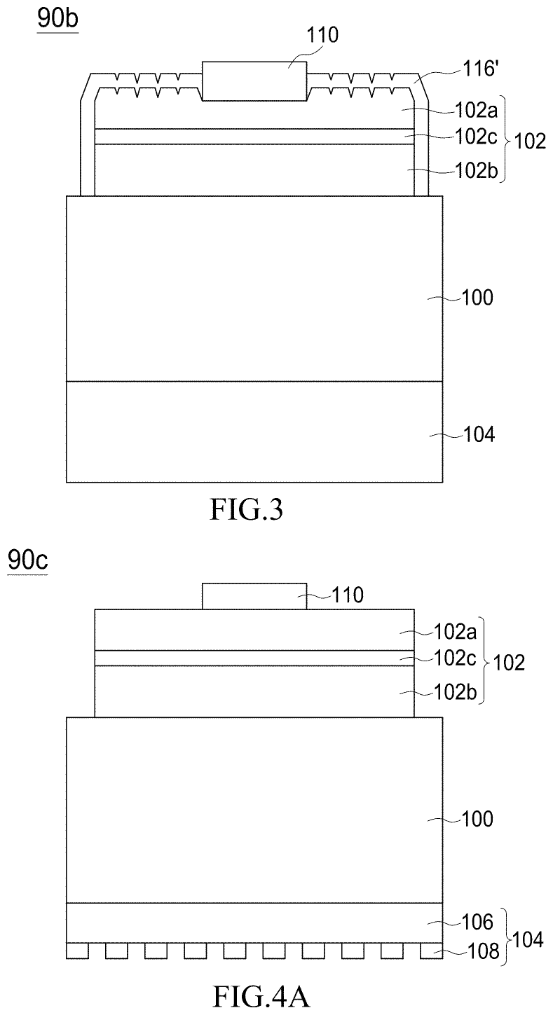

FIG. 3 shows a schematic sectional view of the semiconductor device 90b in accordance with an embodiment of the present disclosure.

This embodiment provides another configuration of the protective layer. As shown in FIG. 3, the protective layer 116′ of this embodiment covers a portion of the base 100, the sidewall of the semiconductor structure 102, and the upper surface of the semiconductor structure 102. In this embodiment, the semiconductor structure 102 has a roughened upper surface, and the protective layer 116′ conformally covers the roughened upper surface and physically contacts the first electrode 110. In an embodiment, the protective layer 116′ may cover a portion of an upper surface of the main electrode 110a. For example, the protective layer 116′ may cover not more than 20% or not more than 10% of the upper surface area of the main electrode 110a. In an embodiment, the protective layer 116′ covers a portion of the upper surface of the main electrode 110a and also covers the extension electrode 110b. In an embodiment, the protective layer 116′ only covers the extension electrode 110b and does not cover the upper surface of the main electrode 110a. The material of the protective layer 116′ may include a silicon nitride or silicon oxide, such as SiO₂ or SiNₓ. The thickness of the protective layer may be in the range of 1000 Å to 8000 Å (such as 1500 Å, 2000 Å, 3000 Å, 6000 Å, 6500 Å, 7000 Å, or 7500 Å). The conductive reflective structure 104 in this embodiment can be as described in any embodiment of the present disclosure. For the positions, materials, and related descriptions of other layers or structures, the foregoing embodiments can be referred to, and are not repeatedly described herein.

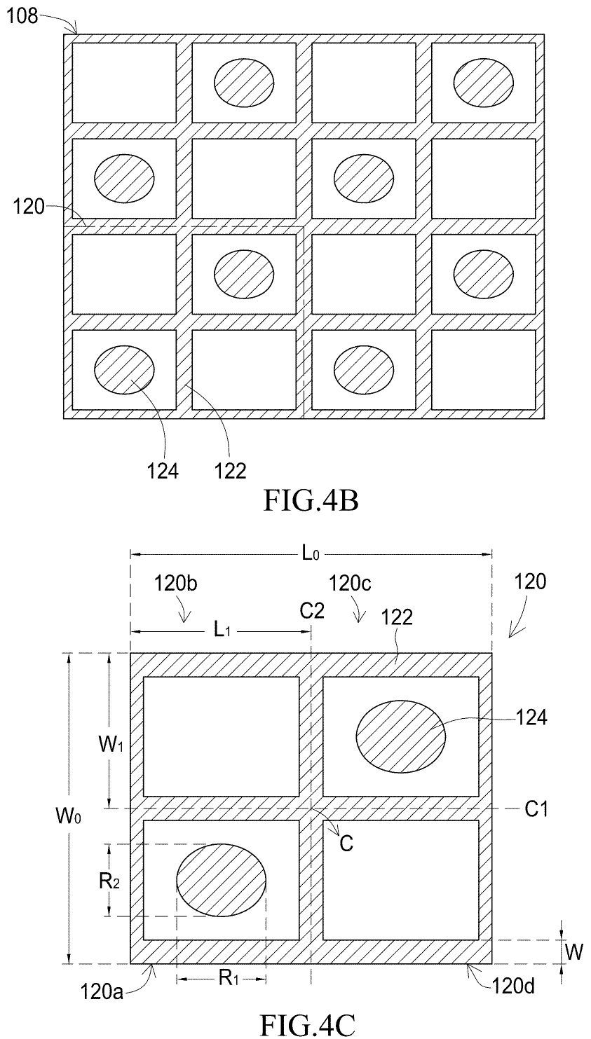

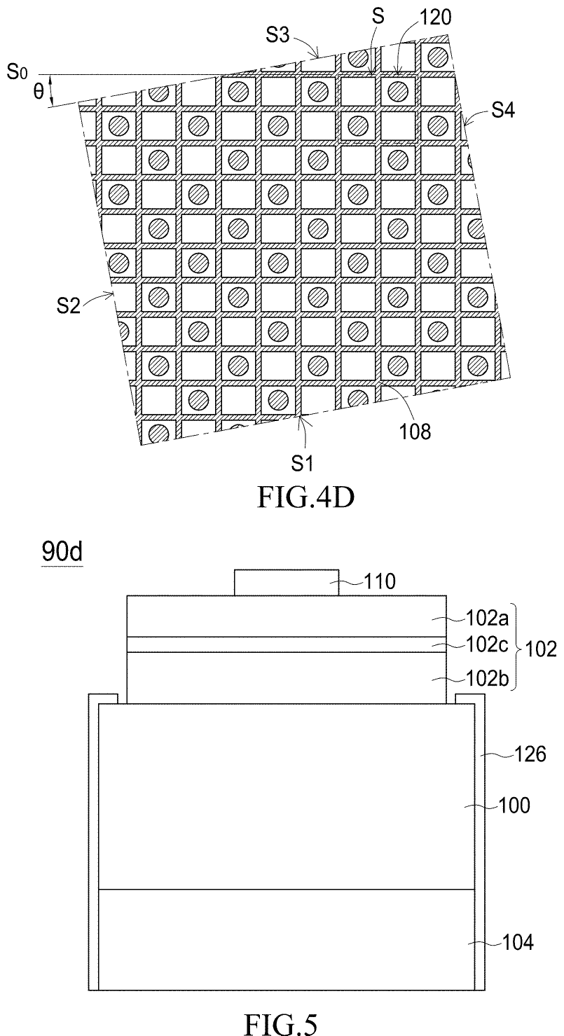

FIG. 4A shows a schematic sectional view of the semiconductor device 90c in accordance with an embodiment of the present disclosure.

As shown in FIG. 4A, the conductive reflective structure 104 includes a metal oxide structure 106 and a patterned metal structure 108. In another embodiment, the conductive reflective structure 104 may not include the metal oxide structure 106, and the metal structure 108 may be directly formed on the base 100. As mentioned above, the patterned metal structure 108 may cover and physically contact the metal oxide structure 106 or the base 100. The patterned metal structure 108 may be composed of a single metal layer or multiple metal layers. The material of the metal layer may include metal or alloy. For the material and structural variations of the metal layer, the foregoing embodiments can be referred to.

FIG. 4B shows a schematic view of a patterned metal structure in accordance with an embodiment of the present disclosure.

The patterned metal structure 108 may include a plurality of unit patterns 120. Each unit pattern 120 may include a first graphic 122 and/or a second graphic 124. The first graphic 122 and the second graphic 124 may be respectively selected from ellipse, circle, triangle, rectangle or polygon. As shown in FIG. 4B, each unit pattern 120 may be composed of a plurality of squares (i.e. the first graphic 122) and/or a plurality of circles (i.e. the second graphic 124). The plurality of unit patterns 120 can be repeatedly arranged to form a pattern as shown in FIG. 4B. FIG. 4B only shows four unit patterns 120. However, the present disclosure is not limited thereto. In an embodiment, a ratio of the area of the patterned metal structure 108 to the area of a surface of the base 100 (such as the second surface 100b) may be in the range of 20% to 80%, such as 25%, 30%, 35%, 40%, 45%, 50%, 55%, 60%, 65%, 70%, or 75%. It should be noted that FIG. 4B is for illustrative purposes only. A person having ordinary skill in the art should understand that the number of unit patterns 120 in the patterned metal structure 108 may vary depending on factors such as the size of the semiconductor device. In addition, the unit pattern(s) 120 located near a side edge of the semiconductor device may be incomplete since there may be a dicing process in manufacturing of the device, by which the unit pattern(s) 120 located near the side edge may be cut off and only a part of the unit pattern(s) 120 is left on the semiconductor device.

FIG. 4C shows an enlarged view of the unit pattern 120 in FIG. 4B.

As shown in FIG. 4C, an outline (or a profile) of the unit pattern 120 has a rectangular shape, and has a length L₀ and a width W₀. The length L₀ and the width W₀ may be respectively in a range of 120 nm to 200 nm, such as 140 nm, 160 nm, or 180 nm. The unit pattern 120 can be divided into a first region 120a, a second region 120b, a third region 120c, and a fourth region 120d by an imaginary line C1 and an imaginary line C2 that pass through the center point C of the unit pattern 120. The imaginary line C1 and the imaginary line C2 are perpendicular to each other and intersect at the center point C. Designs of the first region 120a and the third region 120c may be symmetrical to each other, and the designs of the second region 120b and the fourth region 120d may be symmetrical to each other. In this embodiment, the designs of the first region 120a and the third region 120c are symmetrical with respect to the center point C, and the designs of the second region 120b and the fourth region 120d are symmetrical with respect to the center point C. The designs of the first region 120a and the second region 120b are different. In this embodiment, the first region 120a, the second region 120b, the third region 120c, and the fourth region 120d are connected to each other. The first region 120a, the second region 120b, the third region 120c, and the fourth region 120d respectively have a first graphic 122. As shown in FIG. 4C, the first graphic 122 may be a hollow rectangle having a line width W. The line width W may be in a range of 1 nm to 10 nm, such as 2 nm, 3 nm, 4 nm, 5 nm, 6 nm, 7 nm, 8 nm, or 9 nm. The first graphic 122 may have a length L₁ and a width W₁. The length L₁ and the width W₁ may be respectively in a range of 50 nm to 100 nm, such as 55 nm, 60 nm, 65 nm, 70 nm, 75 nm, 80 nm, 85 nm, 90 nm, or 95 nm.

The first region 120a and the third region 120c may respectively include a second graphic 124, which may be located inside the first graphic 122 and may be surrounded by the first graphic 122. The second graphic 124 may be an ellipse, a circle, a triangle, a rectangle, or a polygon. In this embodiment, the second graphic 124 is different from the first graphic 122 and is not rectangular. When the second graphic 124 is an ellipse, it has a long axis length R₁ and a short axis length R₂, and R₁>R₂. When the second figure is a circle, R₁ is equal to R₂. R₁ and R₂ may be respectively in the range of 20 nm to 60 nm, such as 25 nm, 30 nm, 35 nm, 40 nm, 45 nm, 50 nm, or 55 nm. In an embodiment, the unit pattern 120 has a square outline, that is, the length L₀ is equal to the width W₀. In an embodiment, the outline of the first graphic 122 in each of the first region 120a, the second region 120b, the third region 120c, and the fourth region 120d is square (i.e., the length L₁ is equal to the width W₁), and the outline of the second graphic 124 is circular (i.e., R₁=R₂). As shown in FIG. 4C, in this embodiment, the second region 120b and the fourth region 120d only have the first graphic 122 and do not have the second graphic 124.

In an embodiment, an area defined by the outline of the unit pattern 120 is A₀ (i.e., the area obtained by multiplying the length L₀ with the width W₀ as shown in FIG. 4C) and the sum of the areas of all the first graphics 122 and the second graphics 124 in the unit pattern 120 is A₁ (the hatched region as shown in FIG. 4C). In some embodiments, 20%≤(A₁/A₀)*100%≤75%. Specifically, (A₁/A₀)*100% may be 25%, 30%, 35%, 40%, 45%, 50%, 55%, 60%, 65%, 70%, or 75%. Thereby, the photoelectric characteristics of the semiconductor device can be further improved. For example, the forward voltage (vf) of the semiconductor device can be reduced while maintaining the light-emission intensity and the contact characteristics.

In some embodiments, when 20%≤(A₁/A₀)*100%≤75%, the forward voltage (vf) of the semiconductor device at a current of 50 mA may be in the range of 0.8V to 0.95V, such as 0.85V or 0.9V, and a luminous power of the semiconductor device can be at least in a range of 2 mW to 4 mW, such as 2.5 mW, 2.8 mW, 3 mW, 3.2 mW, or 3.5 mW.

FIG. 4D shows a schematic view of the patterned metal structure 108 in accordance with an embodiment of the present disclosure.

FIG. 4D can be a bottom view of a semiconductor device 90c according to an embodiment. The outermost dashed frame represents the outline of the base 100 in the semiconductor device 90c, and the outline is composed of a plurality of sides of the base 100. Specifically, the base 100 of this embodiment includes a side S1, a side S2, a side S3, and a side S4. As shown in FIG. 4D, the patterned metal structure 108 may represent a design formed by repeatedly arranging a plurality of unit patterns 120. In the embodiment, one of the unit patterns 120 has a side S, and an imaginary line S0 can be obtained by extending the side S in a horizontal direction. Among the plurality of sides of the base 100, the side closest to the side S is the side S3. As shown in FIG. 4D, an included angle θ may exist between the side C and the imaginary line S0. In an embodiment, 0°<0<90°, such as 10°, 15°, 20°, 25°, 30°, 35°, 40°, 45°, 50°, 55°, 60°, 65°, 70°, 75°, 80°, or 85°. Thereby, the possibility of damaging the metal structure 108 during a dicing process can be reduced in the manufacturing of the semiconductor device.

It should be noted that FIG. 4D is for illustrative purposes only. A person having ordinary skill in the art should understand that the number of unit patterns 120 in the patterned metal structure 108 may vary depending on factors such as the size of the semiconductor device. In addition, the unit pattern(s) 120 located near the side edge of the semiconductor device may be incomplete since there may be a dicing process in manufacturing of the device, by which the unit pattern(s) 120 located near the side edge may be cut off and only a part of the unit pattern(s) 120 is left on the semiconductor device. For the positions, materials, and related descriptions of other layers or structures, the foregoing embodiments can be referred to, and are not repeatedly described herein.

FIG. 5 shows a schematic sectional view of the semiconductor device 90d in accordance with an embodiment of the present disclosure.

The semiconductor device 90d of this embodiment further includes a cover layer 126 for protecting the metal oxide structure 106 and/or the metal structure 108. As shown in FIG. 5, the cover layer 126 may cover a side wall and a portion of the upper surface of the base 100 and a side wall of the conductive reflective structure 104. In some embodiments, the material of the cover layer 126 may include a silicon nitride or silicon oxide, such as SiO₂, or SiNₓ. In some embodiments, the material of the cover layer 126 may include a metal oxide such as aluminum oxides (e.g. Al₂O₃). In some embodiments, the cover layer 126 may be formed by atomic layer deposition (ALD). In some embodiments, when the metal structure 108 contains a highly active metal element such as silver (Ag), the presence of the cover layer 126 can improve the accelerated deterioration of the metal structure due to environmental factors (such as high temperature or high humidity) and can improve the reliability of the semiconductor device. The conductive reflective structure 104 in this embodiment can be as described in any embodiment of the present disclosure. For the positions, materials, and related descriptions of other layers or structures, the foregoing embodiments can be referred to, and are not repeatedly described herein.

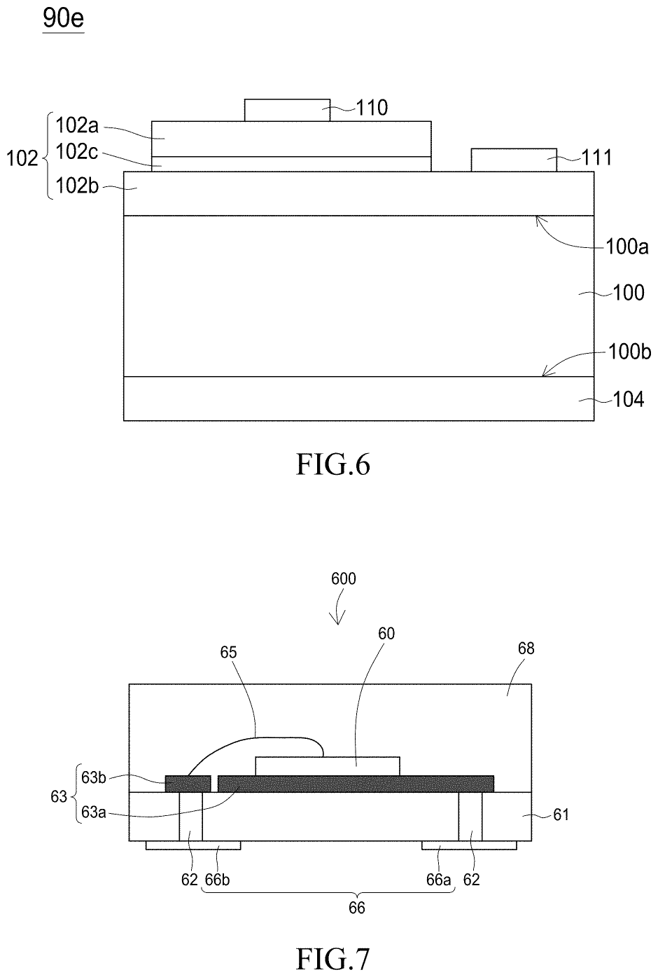

FIG. 6 shows a schematic sectional view of the semiconductor device 90e in accordance with an embodiment of the present disclosure.

The semiconductor device 90e of this embodiment includes a base 100, a semiconductor structure 102, a conductive reflective structure 104, a first electrode 110, and a second electrode 111. The base 100 has a first surface 100a and a second surface 100b opposite to the first surface 100a. The semiconductor device 90e of this embodiment is a horizontal type semiconductor light-emitting device. That is, two electrodes (the first electrode 110 and the second electrode 111) are located on the same side of the base 100. In the embodiment, the first electrode 110 and the second electrode 111 are both located on the first surface 100a. The first electrode 110 and the second electrode 111 can be used for electrical connecting to an external power source and the semiconductor structure 102.

The semiconductor structure 102 is located on the first surface 100a of the base 100 and includes a first semiconductor layer 102a, a second semiconductor layer 102b, and a semiconductor structure 102c between the first semiconductor layer 102a and the second semiconductor layer 102b. The first electrode 110 is located on the first semiconductor layer 102a, and the second electrode 111 is located on the second semiconductor layer 102b. The base 100 may be a conductive substrate including the above-mentioned conductive material, or a non-conductive substrate including an insulating material such as sapphire. The conductive reflective structure 104 in this embodiment can be as described in any embodiment of the present disclosure.

For the positions, materials, and related descriptions of other layers or structures, the foregoing embodiments can be referred to, and are not repeatedly described herein.

FIG. 7 shows a schematic sectional view of a semiconductor package structure in accordance with an embodiment of the present disclosure.

As shown in FIG. 7, a package structure 600 which includes a semiconductor device 60, a package substrate 61, a carrier 63, a bonding wire 65, a contact structure 66 and an encapsulating material 68 is provided. The package substrate 61 may include a ceramic or glass. The package substrate 61 has a plurality of through holes 62. Each through hole 62 may be filled with a conductive material such as metal for electrical conduction and/or heat dissipation. The carrier 63 may be located on a surface of one side of the package substrate 61 and may also contain a conductive material such as metal. The contact structure 66 is on a surface on another side of the package substrate 61. In the embodiment, the contact structure 66 includes a first contact pad 66a and a second contact pad 66b, and the first contact pad 66a and the second contact pad 66b can be electrically connected to the carrier 63 through the through holes 62. In an embodiment, the contact structure 66 may further include a thermal pad (not shown), for example, between the first contact pad 66a and the second contact pad 66b.

The semiconductor device 60 is located on the carrier 63. In this embodiment, the semiconductor device 60 is shown in FIG. 7; however, it can be replaced by the semiconductor device as described in any embodiment of the present disclosure. In the embodiment, the carrier 63 includes a first portion 63a and a second portion 63b, and the semiconductor device 60 is electrically connected to the second portion 63b of the carrier 63 by a bonding wire 65. The material of the bonding wire 65 may include metal, such as gold (Au), silver (Ag), copper (Cu), or aluminum (Al), or may include alloy containing at least one of the above elements. The encapsulating material 68 can cover the semiconductor device 60 and has the effect of protecting the semiconductor device 60. Specifically, the encapsulating material 68 may include a resin material, such as an epoxy resin, or a silicone resin. The encapsulating material 68 may further include a plurality of wavelength conversion particles (not shown) to convert a first light emitted by the semiconductor device 60 into a second light. The wavelength of the second light is greater than the wavelength of the first light.

Based on above, the semiconductor device provided in the present disclosure may exhibit improved optical-electrical characteristics, such as light-emitting efficiency, wavelength stability and/or device reliability. Specifically, the semiconductor device of the present disclosure can be applied to products in various fields, such as illumination, medical care, display, communication, sensing, or power supply system. For example, the semiconductor device can be used in a light fixture, monitor, mobile phone, or tablet, an automotive instrument panel, a television, computer, wearable device (such as watch, bracelet or necklace), traffic sign, outdoor display device, or medical device.

It should be realized that each of the embodiments mentioned in the present disclosure is only used for describing the present disclosure, but not for limiting the scope of the present disclosure. Any obvious modification or alteration is not departing from the spirit and scope of the present disclosure. Furthermore, above-mentioned embodiments can be combined or substituted under proper condition and are not limited to specific embodiments described above. A connection relationship between a specific component and another component specifically described in an embodiment may also be applied in another embodiment and is within the scope as claimed in the present disclosure.

What is claimed is:

1. A semiconductor device, comprising:
a base having a first surface and a second surface opposite to the first surface;
a semiconductor structure located on the first surface; and
a conductive reflective structure, located on the second surface and comprising a metal oxide structure and a metal structure;
wherein the metal oxide structure is located between the metal structure and the base, and the metal oxide structure physically contacts the second surface.

2. The semiconductor device of claim 1, wherein the metal oxide structure comprises a first metal oxide layer and a second metal oxide layer.

3. The semiconductor device of claim 2, wherein the first metal oxide layer comprises a first conductive material, and the second metal oxide layer comprises a second conductive material having one metal element same as the first conductive material.

4. The semiconductor device of claim 1, wherein the base has a thickness from 60 μm to 250 μm.

5. The semiconductor device of claim 1, wherein the base is a growth substrate.

6. The semiconductor device of claim 1, wherein the metal structure comprises a first metal layer and a second metal layer wider than the metal layer.

7. The semiconductor device of claim 6, wherein the first metal covers a portion of the metal oxide structure.

8. The semiconductor device of claim 1, further comprising a dielectric material layer located between the conductive reflective structure and the base.

9. The semiconductor device of claim 8, wherein the dielectric material layer partially covers the second surface.

10. The semiconductor device of claim 1, further comprising a contact layer located between the conductive reflective structure and the base, wherein the base has a portion and the contact layer covers the portion.

11. The semiconductor device of claim 10, further comprising a dielectric material layer located between the conductive reflective structure and the base, wherein the contact layer and the dielectric material layer are separated in a sectional view of the semiconductor device.

12. The semiconductor device of claim 1, wherein the base is a conductive substrate.

13. The semiconductor device of claim 1, wherein the semiconductor device is a vertical type semiconductor light-emitting device.

14. The semiconductor device of claim 1, wherein the metal structure has a plurality of unit patterns.

15. The semiconductor device of claim 14, wherein each of the plurality of unit patterns comprises a first graphic and/or a second graphic.

16. The semiconductor device of claim 15, wherein the first graphic and the second graphic comprises an ellipse, a circle, a triangle, a rectangle, or a polygon.

17. The semiconductor device of claim 15, wherein each of the plurality of unit patterns has an area A₀, the first graphic and/or the second graphic in each of the plurality of unit patterns have a total area A₁, and 20%≤(A₁/A₀)*100%≤75%.

18. The semiconductor device of claim 1, wherein during operation of the semiconductor device, the semiconductor structure emits a radiation having a peak wavelength of 800 nm to 2000 nm.

19. The semiconductor device of claim 18, wherein the metal structure has a first area, the second surface has a second area, and a ratio of the first area to the second area is 20% to 80%.

20. The semiconductor device of claim 17, wherein the semiconductor device has a light-emitting power in a range of 2 mW to 4 mW when operated at a current of 50 mA.
